(19) United States
(12) Patent Application Publication
(10) Pub. No.: US 2019/0350095 A1
(43) Pub. Date: Nov. 14, 2019

(54) SOLID-STATE MEMORY DEVICE WITH A REMOVABLE SOLID-STATE DRIVE

(71) Applicant: NKI SYSTEMS, LLC, Orlando, FL (US)

(72) Inventor: Liangjing Ding, Orlando, FL (US)

(21) Appl. No.: 16/399,452

(22) Filed: Apr. 30, 2019

Related U.S. Application Data
(60) Provisional application No. 62/670,965, filed on May 14, 2018.

(51) Int. Cl. H05K 5/02; G11C 5/04; G06F 1/18; G06F 1/16

(52) U.S. Cl. CPC H05K 5/026; G11C 5/04; G06F 1/1658; G06F 1/187; H05K 5/0217

(57) ABSTRACT

A solid-state memory device includes a housing having an open end, a printed circuit board within the housing, a first connector carried by the printed circuit board, and a removable solid-state drive having a second connector. In addition, the device includes an end cap having a platform that projects outwards therefrom, and with the solid-state drive being secured to the platform. The end cap is removably inserted into the open end in the housing until the second connector on the solid-state drive mates with the first connector within the housing. The end cap includes a quick release retaining fastener for securing the end cap to the housing. The retaining fastener allows the solid-state drive to be quickly removed from the housing as to be inserted into a corresponding different housing.

### RELATED APPLICATION

The present invention claims the benefit of U.S. Provisional Patent Application Ser. No. 62/670,965 filed May 14, 2018, the entire contents of which are incorporated herein by reference.

### TECHNICAL FIELD

The present disclosure relates to the field of solid-state memory devices, and more particularly, to a solid-state memory device with a removable solid-state drive.

### BACKGROUND

Traditional solid-state memory devices include a solid state drive embedded within a housing. At times the solid state drive may need to be swapped from one drive to another. For example, one of the drives may support data storage, and another one of the drives may support the stored data being read out.

To access the solid state drive, a pair of housing screws first needs to be removed from the housing. Next, a pair of mounting screws needs to be removed from the solid-state drive so that the solid-state drive may be removed from its mating connector. This is a time consuming process.

Accordingly, further improvements in solid state memory devices may be desirable in certain instances.

### SUMMARY

A solid-state memory device with a removable solid-state drive is disclosed. The device includes a housing having an open end and a first connector positioned within the housing. In addition, the device includes a removable solid-state drive having a second connector and an end cap that carries the removable solid-state drive. The end cap is removably inserted into the open end in the housing until the second connector on the solid-state drive mates with the first connector within the housing.

The end cap may have a quick release retaining fastener for securing the end cap to the housing, and the housing may have a first opening and an external connector positioned with the first opening. The quick release retaining fastener may be a spring-loaded knob screw. The housing may have a mounting feature configured to secure to a host device.

In a particular aspect, the first and second connectors may be mSATA connectors, and the external connector may be one of a USB, micro USB, mini USB, USB Type-C, MDP, SATA, Thunderbolt, and eSATA type connector. In addition, the device may include a printed circuit board within the housing, and a bridge controller and the first connector carried by the printed circuit board.

The end cap may include a platform that projects outwards therefrom, and with the solid-state drive being secured to the platform. The platform may have opposing sidewalls to align the solid-state drive when inserted within the housing, and a bumper for each sidewall positioned within the housing to engage the opposing sidewalls of the platform when the second connector on the solid-state drive is mated to the first connector within the housing.

In another particular aspect, a solid-state memory device includes a housing having an open end, a printed circuit board within the housing, a first connector carried by the printed circuit board, and a removable solid-state drive having a second connector. In addition, the device includes an end cap having a platform, that projects outwards therefrom, and with the solid-state drive being secured to the platform. The end cap is removably inserted into the open end in the housing until the second connector on the solid-state drive mates with the first connector within the housing.

In yet another particular aspect, a method of operating a solid-state memory device comprising a housing having an open end, a printed circuit board within the housing, a first connector and an external connector carried by the printed circuit board, a removable solid-state drive having a second connector, and an end cap having a platform that projects outwards therefrom, and with the solid-state drive being secured to the platform, is disclosed. The method includes inserting the end cap into the open end in the housing until the second connector on the solid-state drive mates with the first connector within the housing, and securing the end cap to the housing. In addition, the method includes coupling a host device to the external connector for storing data on the solid-state drive.

The method may also include removing the solid-state drive from the housing and inserting the solid-state drive into a corresponding different housing for reading the data stored on the solid-state drive.

### BRIEF DESCRIPTION OF THE DRAWINGS

FIG. 1 is a perspective view of a solid-state memory device that includes a housing and a solid-state drive removed from the housing in which various aspects of the disclosure may be implemented.

FIGS. 2-3 are perspective views of the solid-state drive partially inserted into the housing illustrated in FIG. 1.

FIG. 4 is a perspective view of the solid-state drive fully inserted into the housing illustrated in FIG. 1.

FIG. 5 is a cut-away perspective view of the housing with the solid-state drive partially inserted into the housing as illustrated in FIG. 3.

FIG. 6 is a cut-away perspective view of the housing with the solid-state drive fully inserted into the housing as illustrated in FIG. 4.

FIGS. 7-8 are perspective views of the housing and the end cap illustrated in FIG. 2 without the solid-state drive being carried by the end cap.

FIG. 9 is a bottom perspective view of another embodiment of the housing as illustrated in FIG. 4, with the housing including a bottom mounting feature.

FIG. 10 is a top perspective view of yet another embodiment of the housing as illustrated in FIG. 9, with a mounting feature on both a top and bottom of the housing.

FIG. 11 is a flowchart illustrating a method for operating a solid-state memory device.

### DETAILED DESCRIPTION

The present description is made with reference to the accompanying drawings, in which exemplary embodiments are shown. However, many different embodiments may be used, and thus the description should not be construed as limited to the particular embodiments set forth herein. Rather, these embodiments are provided so that this disclosure will be thorough and complete. Like numbers refer to like elements throughout, and prime notations are used to indicate similar elements in alternative embodiments.

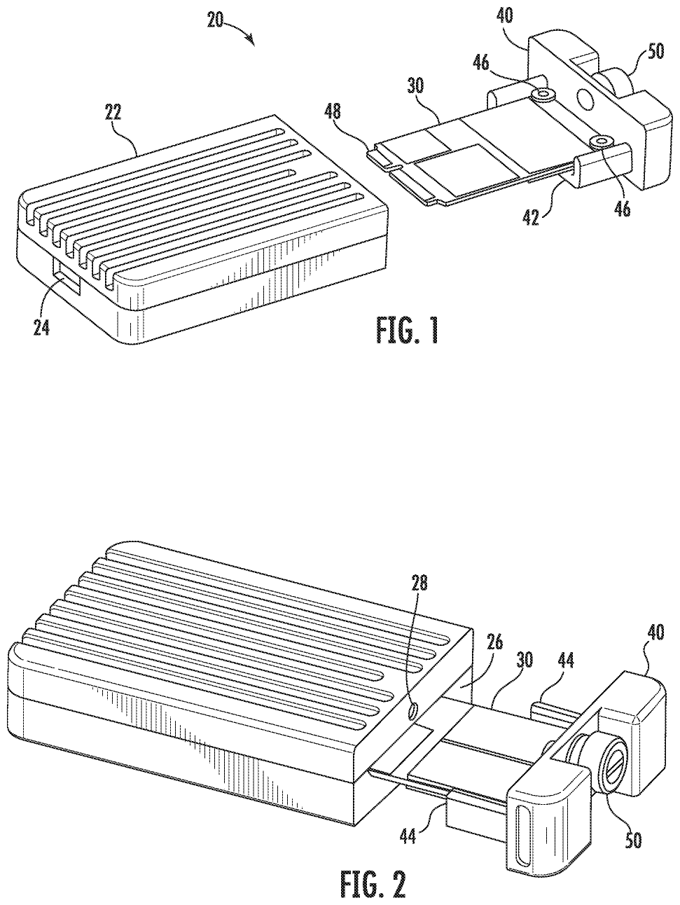

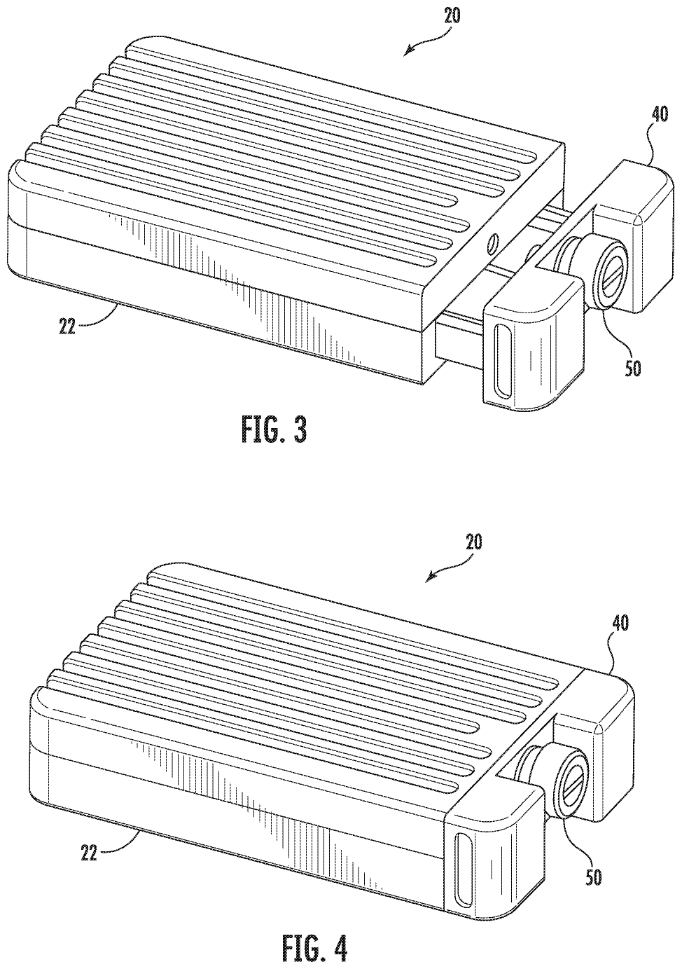

Referring initially to FIGS. 1-4, a solid-state memory device 20 with a removable solid-state drive 30 will be discussed. The solid-state memory device 20 includes a rectangular shaped housing 22 having a first opening 24 at a first end and a second opening 26 at a second end opposite the first end.

The first opening 24 is sized for either an external connector or a cable. As will be discussed in detail below, the removable solid-state drive 30 connects to an internal first connector 58 within the housing 22. The internal first connector 58 may then be connected to an external connector 68 positioned within the first opening 24, or may be hardwired to a cable 55 that extends through the first opening 24. The external connector or cable allows the solid-state memory device 20 to connect to a host device 59, such as a video camera or computer. The second opening 26 is for an end cap 40 that carries the removable solid-state drive 30.

The end cap 40 includes a platform 42 that projects outwards therefrom, and with the solid-state drive 30 being secured to the platform 42. In the illustrated embodiment, a pair of screws 46 is used to secure the solid-state drive 30 to the platform 42. The use of screws is not to be limiting. Other forms of securing the solid-state drive 30 to the platform 42 may be used.

The platform 42 further includes side walls 44 that function as a guide when the solid-state drive 30 is inserted into the second opening 26. The side walls 44 align a second connector 48 on the solid-state drive 30 for mating with a corresponding connector within the housing 22. The second connector 48 may be a mSATA male connector 48, and the corresponding internal first connector 58 within the housing 22 may be a mSATA female connector.

Once the solid-state drive 30 is mated with the corresponding internal female connector within the housing 22, then the end cap 40 is to be secured in place to the housing 22. The end cap 40 further includes a retaining fastener 50 for securing the end cap 40 to the housing 22. In the illustrated embodiment, the retaining fastener 50 is a spring-loaded knob screw. When the knob screw is pushed and turned, a threaded shaft extends outwards to engage a threaded opening 28 at the second end of the housing 22.

The retaining fastener 50 advantageously allows the solid-state drive 30 to be quickly removed from the housing 22. This is helpful when the solid-state drive 30 has been used for data storage, and now the data needs to be read by a data reader. The solid-state drive 30 is easily removed from one housing so as to be inserted into a corresponding different housing.

In one embodiment, the external connector 68 and/or cable 55 within the first opening 24 in the housing 22 supports data storage within the solid-state drive 30. In a different embodiment, the external connector 68 and/or cable 55 is to support the stored data being read from the solid-state drive 30. The solid-state drive 30 is quickly interchangeable between the different housings to support either a data storage function or a card reader function.

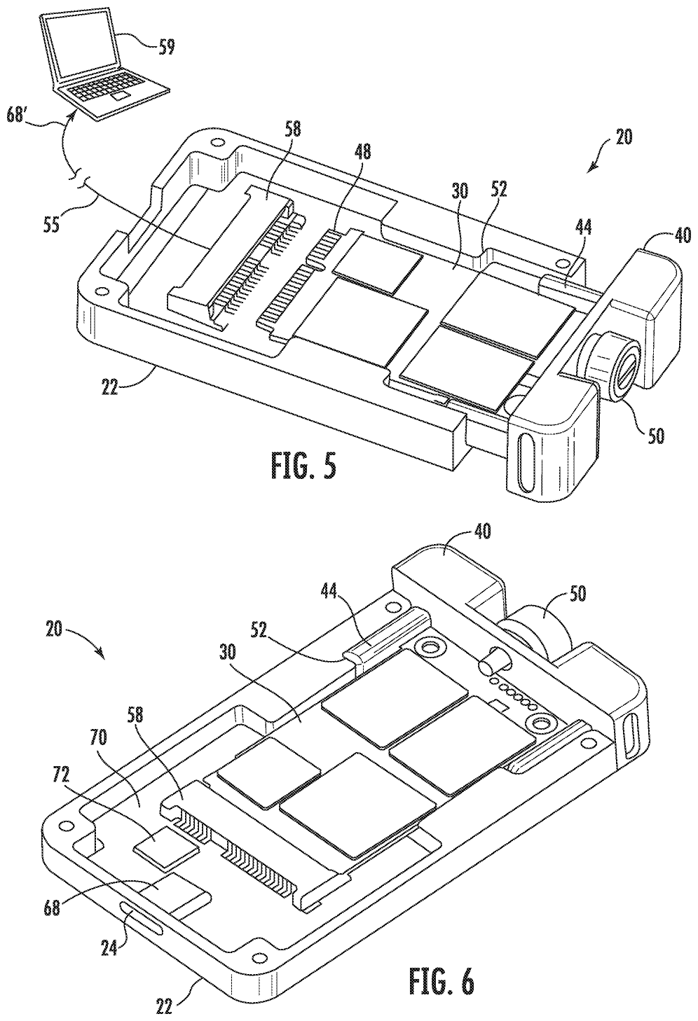

Referring now to FIGS. 5 and 6, a cut-away view of the housing 22 with the end cap 40 partially and fully inserted into the housing 22 will be discussed. With the end cap 40 partially inserted, the second connector 48 on the solid-state drive 30 is spaced apart from the corresponding internal first connector 58 within the housing 22.

In one embodiment, the internal first connector 58 is connected to an external connector 68 positioned within the first opening 24. In another embodiment, the internal first connector 58 is hardwired to a cable 55 that extends through the first opening 24. The end of the cable 55 opposite the internal first connector 58 includes the external connector 68′. As noted above, the second connector 48 may be a mSATA male connector, and the corresponding internal first connector 58 may be a mSATA female connector.

The solid-state memory device 20 may further include a bridge controller 72. The bridge controller 72 is carried on a printed circuit board 70 that also carries the internal first connector 58. The external connector 68 may be a USB, Micro USB, Mini, USB, USB Type-C (shown), Thunderbolt, SATA, eSATA or another type connector. The bridge controller 72 connects the mSATA connector 58 to the USB Type-C external connector 68. The bridge controller 72 may be, for example, SATA to USB 2.0, SATA to USB 3.0, SATA to USB 3.1 Gen 1, SATA to USB 3.1 Gen 2, or SATA to Thunderbolt, etc.

As also illustrated in the cut-away view of the housing 22, the side walls 44 of the platform 42 function as a guide when the solid-state drive 30 is inserted into the second opening 26. The housing 22 includes a bumper 52 for each sidewall 44 to prevent the solid-state drive 30 from being inserted to far within the housing 22 and possibly causing damage to the connectors 48, 58.

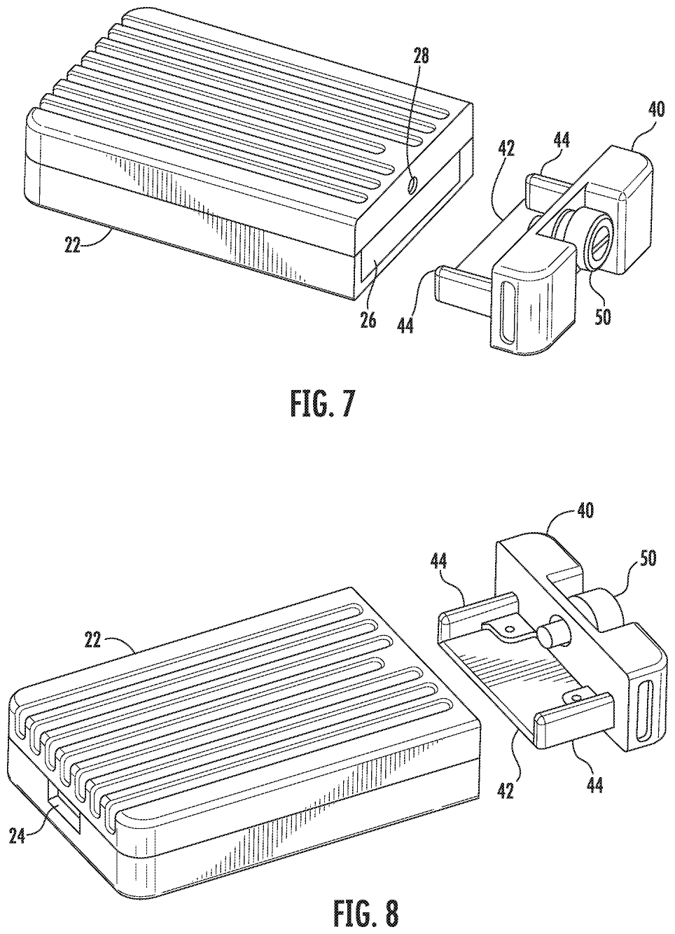

Perspective views of the housing 22 and the end cap 40 without the solid-state drive 30 being carried by the end cap are provided in FIGS. 7 and 8 for reference purposes.

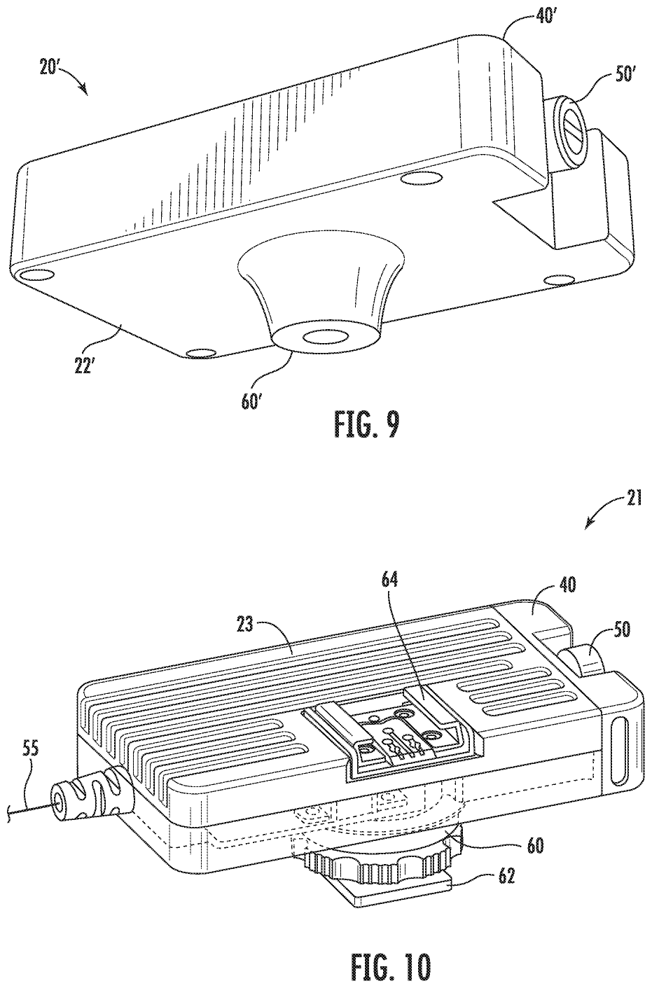

Referring now to FIG. 9, another embodiment of the housing 22′ is provided with a bottom mounting feature 60. The bottom mounting feature 60 allows the solid-state memory device 20′ to be mounted to a host device 59, such as a camera or computer, for example. The bottom mounting feature 60 may include a threaded opening, for example.

In yet another embodiment as illustrated in FIG. 10, the housing 23 includes a top mounting feature 64 in addition to the bottom mounting feature 60. The bottom mounting feature 60 includes an accessory connector 62 configured to be inserted into a mounting point (e.g., a “hot shoe”) on a top of a camera, for example. As those of ordinary skill in the art can appreciate, a hot shoe comprises an angled metal bracket surrounding a metal contact point which can be used to make an electrical connection between the camera and an accessory such as a flash unit or the solid-state memory device 21.

Accordingly, the top mounting feature 64 comprises a hot shoe so that when the solid-state memory device 2168′ is secured to the hot shoe of the camera, a flash unit can be connected to the camera via the top mounting feature 64 and the flash used. The top mounting feature 64 and the accessory connector 62 are in electrical communication with each other through circuitry (e.g., printed circuit board 70) of the solid-state memory device 21 so that the hot shoe of the camera is accessible to the flash unit and fully functioning with TTL flash triggering, etc. The cable 55 can also be coupled to the camera for data storage as explained above even when the solid-state device 21 is secured to the hot shoe of the camera.

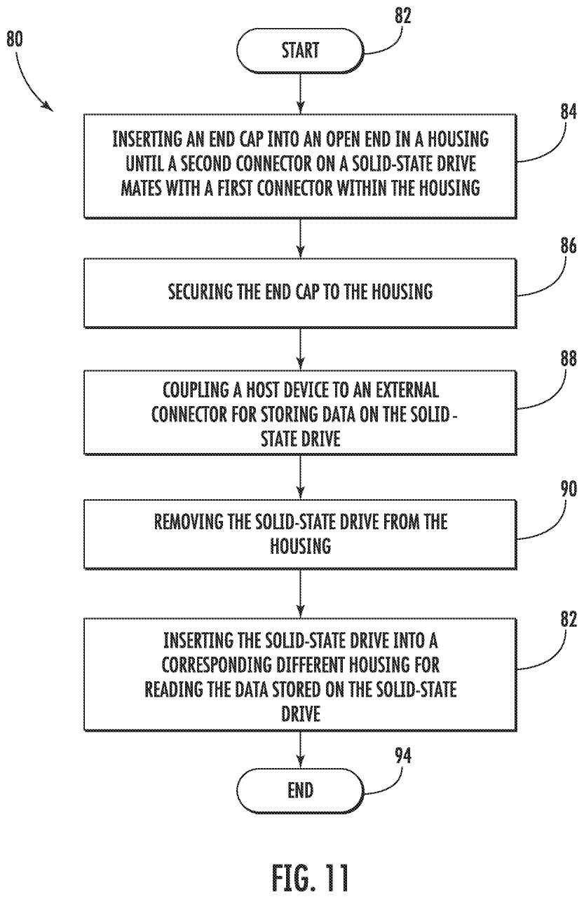

Referring now to the flowchart 80 in FIG. 11, and generally speaking, a method of operating the solid-state memory device illustrated in FIGS. 1-10 will be discussed.

From the start, at 82, the method includes inserting an end cap into an open end in a housing until a second connector on a solid-state drive mates with a first connector within the housing, at 84. The method also includes, at 86, securing the end cap to the housing. In addition, the method includes coupling, at 88, a host device to the external connector for storing data on the solid-state drive. The method may also include, at 90, removing the solid-state drive from the housing and, at 92, inserting the solid-state drive into a corresponding different housing for reading the data stored on the solid-state drive. The method ends at 94.

Many modifications and other embodiments will come to the mind of one skilled in the art having the benefit of the teachings presented in the foregoing descriptions and the associated drawings. Therefore, it is understood that the disclosure is not to be limited to the specific embodiments disclosed, and that modifications and embodiments are intended to be included.

That which is claimed is:

1. A solid-state memory device comprising:
a housing having an open end;
a first connector positioned within the housing;
a removable solid-state drive having a second connector; and
an end cap that carries the removable solid-state drive, wherein the end cap is removably inserted into the open end in the housing until the second connector on the solid-state drive mates with the first connector within the housing.

2. The solid-state memory device of claim 1, wherein the end cap has a quick release retaining fastener for securing the end cap to the housing.

3. The solid-state memory device of claim 2, wherein the housing has a first opening and an external connector positioned with the first opening.

4. The solid-state memory device of claim 2, wherein the first connector is hardwired to a cable that extends through the first opening.

5. The solid-state memory device of claim 2, wherein the first and second connectors comprise mSATA connectors.

6. The solid-state memory device of claim 3, wherein the external connector comprises one of a USB, micro USB, mini, USB, USB Type-C, MDP, SATA, and eSATA type connector.

7. The solid state memory device of claim 1, further comprising a printed circuit board within the housing.

8. The solid-state memory device of claim 7, further comprising a bridge controller carried by the printed circuit board.

9. The solid-state memory device of claim 8, wherein the printed circuit board carries the first connector.

10. The solid state memory device of claim 1, wherein the end cap comprises a platform that projects outwards therefrom, and with the solid-state drive being secured to the platform.

11. The solid state memory device of claim 10, wherein the platform comprises opposing sidewalls to align the solid-state drive when inserted within the housing.

12. The solid state memory device of claim 11, wherein the housing comprises a bumper for each sidewall and positioned within the housing to engage the opposing sidewalls of the platform when the second connector on the solid-state drive is mated to the first connector within the housing.

13. The solid state memory device of claim 2, wherein the quick release retaining fastener comprises a spring-loaded knob screw.

14. The solid state memory device of claim 1, wherein the housing has a bottom mounting feature configured to secure to a host device and a top mounting feature, wherein the top mounting feature comprises a hot shoe.

15. A solid-state memory device comprising:
a housing having an open end;
a printed circuit board within the housing;
a first connector carried by the printed circuit board;
a removable solid-state drive having a second connector; and
an end cap having a platform that projects outwards therefrom, and with the solid-state drive being secured to the platform, wherein the end cap is removably inserted into the open end in the housing until the second connector on the solid-state drive mates with the first connector within the housing.

16. The solid-state memory device of claim 15, wherein the end cap has a quick release retaining fastener for securing the end cap to the housing.

17. The solid-state memory device of claim 15, wherein the housing having a first opening and an external connector positioned with the first opening.

18. The solid-state memory device of claim 17, wherein the external connector comprises one of a USB, micro USB, mini, USB, USB Type-C, MDP, SATA, and eSATA type connector.

19. The solid-state memory device of claim 17, further comprising a bridge controller carried by the printed circuit board.

20. A method of operating a solid-state memory device comprising a housing having an open end, an external connector, a printed circuit board within the housing and coupled to the external connector, a first connector carried by the printed circuit board, a removable solid-state drive having a second connector, and an end cap having a platform that projects outwards therefrom, and with the solid-state drive being secured to the platform, the method comprising:
inserting the end cap into the open end in the housing until the second connector on the solid-state drive mates with the first connector within the housing;
securing the end cap to the housing; and
coupling a host device to the external connector for storing data on the solid-state drive.

21. The method of using the solid-state memory device of claim 20, further comprising:
removing the solid-state drive from the housing; and
inserting the solid-state drive into a corresponding different housing for reading the data stored on the solid-state drive.
